(19) United States
(12) Patent Application Publication
(10) Pub. No.: US 2006/0286694 A1
(43) Pub. Date: Dec. 21, 2006

(54) Method for fabricating LED

(75) Inventors: Bor-Jen Wu, Taipei County (TW); Mei-Hui Wu, Chiayi County (TW); Ken Kai-fu Chang, Shulin City (TW); Chien-An Chen, Sinjhuang City (TW); Yuan-Hsiao Chang, Taipei City (TW); Li-Shei Yeh, Taoyuan City (TW)

Correspondence Address: BACON & THOMAS, PLLC, 625 SLATERS LANE, FOURTH FLOOR, ALEXANDRIA, VA, 22314, US

(73) Assignee: Unit Light Technology Inc., Taoyuan Hsien (TW)

(21) Appl. No.: 11/455,839

(22) Filed: Jun. 20, 2006

(30) Foreign Application Priority Data
Jun. 21, 2005 (TW) 094120604

(51) Int. Cl. H01L 21/00

(52) U.S. Cl. 438/22

(57) ABSTRACT

A high etching selective layer and a light emitting structure are formed subsequently on a semiconductor substrate. Then, a p-type Ohmic contact layer and a metal substrate are formed subsequently on the light emitting structure. The semiconductor substrate and the high etching selective layer are removed. Next, an n-type electrode and a transparent conductive layer are formed adjacent to surface of the light emitting structure opposite to the metal layer.

### FIELD OF THE INVENTION

The present invention relates generally to a method for fabricating LED, and more particularly to a method for increasing emitting efficiency via removing the light-absorbing substrate and forming a transparent conductive layer on the n-type conductive semiconductor layer.

### BACKGROUND OF THE INVENTION

On the grounds that the light emitting device of LED structure possesses a variety of character, the application of the modern industry and people living is in widespread use. As an analogy, LED provides a small emitting area when needing the illuminating within a small region is required. And the rate of the power consumption of LED is far lower than that of the tradition incandescent lamp. Further, seeing that band width of the spectrum of the light rays emitted by from LED is narrow than that of the traditional lighting device, LED may permit emitting the illumination light rays with certain specific frequency band. LED owns various kinds of colors such as red, yellow, green, blue green, blue, etc. LED with the dissimilar color could be employed to indicate different status.

The current LED is shown in FIG. 1, the device includes a light emitting structure formed on the substrate 10. The substrate includes an n-type conductive semiconductor layer 22 on the substrate 10. An active layer 24 is on the n-type conductive semiconductor layer 22, a p-type conductive semiconductor layer 26 is formed on the active layer 24. An n electrode 23 is formed under the substrate 10. More, a p electrode 27 is created on the p-type conductive semiconductor layer 26. A transparent conductive layer 28 could be optionally formed on the p-type conductive semiconductor layer 26.

Providing that most of the current flow from p electrode 27 toward through the p-type conductive semiconductor layer 26 directly, then the hole-electron combination occurs within a small area on the active layer 24 only. The main purpose of the transparent conductive layer 28 is to allow the current of the p type electrode 27 would diffuse on the transparent conductive layer 28 evenly. Afterwards, the current flows downward to p-type conductive semiconductor layer 26 evenly. This could lead to more efficient use of the injected current and more even distribution of lighting area, and hence higher efficiency of LED operation.

It is difficult to form an Ohmic contact between the ITO and the p-type conductive semiconductor layer 26, as a consequence, leads to hinder the current flowing from the transparent layer toward the p-type conductive semiconductor layer 26. Accordingly, the fabricating of LED is arduous and the yield rate of the product is low.

One of the solutions is to search other transparent conductive material which has better Ohmic contact when it contacts with the p-type conductive semiconductor layer. Nevertheless, all the nowadays transparent conductive material has better Ohmic contact with the n-type conductive semiconductor layer. It's exhausting to discover the transparent conductive material having an Ohmic contact with the p-type conductive semiconductor layer.

Correspondingly, it is yearning to demand a solution of fabricating LED for increasing the emitting area of LED to address the foregoing problems.

### SUMMARY OF THE INVENTION

According to the background of the invention, it's aware of plenty problems and defects of the traditional LED. The main purpose of the present invention provides a method for fabricating LED, the LED wherein includes forming a transparent conductive layer with the material of the Indium Tin Oxide (ITO) on the n-type conductive semiconductor layer and forming a proper metal Ohmic contact layer and metal substrate on the p-type conductive semiconductor layer. The light rays emitted from the n-type conductive semiconductor layer in the present invention, it is suitable with the transparent conductive material having the Ohmic contact with the n-type conductive semiconductor layer.

The other purpose of the present invention is increasing the efficiency of utilizing emitting area of LED. The increase results from the current diffusing on the transparent conductive layer and n-type conductive semiconductor layer evenly with the Ohmic contact between the transparent conductive material and n-type conductive semiconductor layer.

The further purpose of the present invention is adopting the lift-off process for removing the semiconductor substrate.

The further purpose of the present invention is that the light rays emitted toward the p-type conductive semiconductor layer turned to reflect toward the n-type conductive semiconductor layer via the metal substrate. More, the metal substrate could be a p electrode and could promote the heat dissipation for LED.

According to the foregoing purposes, the present invention provides a method for fabricating LED, the method wherein includes forming a high etching selective ration layer on the semiconductor substrate. And the light emitting structure includes an n-type conductive semiconductor layer on the high etching selective ratio layer and a p-type conductive semiconductor layer on the n-type conductive semiconductor layer. Afterwards, form a p-type Ohmic contact layer on the light emitting structure and forming a metal layer on the p-type Ohmic contact layer. Then, remove the semiconductor substrate and the high etching selective ratio layer. And form a n-type contact electrode and a transparent conductive layer as the ITO adjacent to the foregoing n-type conductive semiconductor layer.

### BRIEF DESCRIPTION OF THE DRAWINGS

FIG. 1 represents the structure of the traditional LED.

FIG. 2 represents the process for the steps of fabricating LED of one embodiment in the present invention.

FIG. 3 represents the structure illustration of every step of fabricating LED of one embodiment in the present invention.

FIG. 4 represents the structure of one LED device that has been cut.

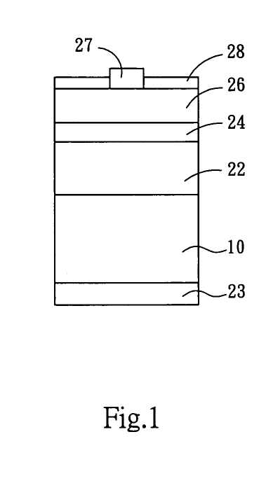

### DETAILED DESCRIPTION OF THE PREFERRED EMBODIMENT

The present invention is described with the preferred embodiments and accompanying drawings. It should be appreciated that all the embodiments are merely used for illustration. Hence, the present invention can also be applied to various embodiments other than the preferred embodiments. Besides, the present invention is not limited to any embodiment but to the appending claims and their equivalents.

The object of the present invention is to form a transparent conductive layer on the n-type conductive semiconductor layer. The interface between the transparent conductive layer and the n-type conductive semiconductor layer forms a better Ohmic contact. And the illumination of LED would emit from the n-type conductive semiconductor layer. Accordingly, removing the semiconductor substrate is essential and it's preferred to adopt the lift-off process for removing the semiconductor substrate. Additionally, a metal substrate would be formed on the p-type conductive semiconductor layer. The metal substrate includes a p electrode and a function of enhancing heat dissipation for LED.

Consequently, the present invention provides a method for fabricating LED. The method comprises forming a high etching selective ratio layer on a semiconductor substrate layer. Afterwards, a light emitting structure is formed on the high etching selective ratio layer. Aforementioned light emitting structure includes an n-type conductive semiconductor layer on the high etching selective ratio layer and a p-type conductive semiconductor layer on the n-type conductive semiconductor layer. Additionally, a p-type Ohmic contact layer is stacked on the light emitting structure. And after that a thick metal layer is then formed on the p-type Ohmic contact layer. Moreover, the next step is to remove the semiconductor substrate and high etching selective ratio layer. Thereafter, n-type contact electrodes and a transparent conductive layer are formed is adjacent to the n-type conductive semiconductor layer, wherein the transparent conductive layer includes Indium Tin Oxide (ITO).

The foregoing semiconductor substrate is a III-V compound semiconductor substrate. Preferably, GaAs could be used to act as the substrate. The aforementioned high etching selective ratio layer includes AlAs or AlGaAs. The steps for forming p-type Ohmic contact layer include forming a p-type metal contact layer on the p-type semiconductor layer. Furthermore, the semiconductor substrate should be removed via the high etching selective ratio layer by Hydrofluoric Acid. Cutting the semiconductor substrate to expose the high etching selective ratio layer would help to improve the lift-off process yield. However, the cutting step is optional. Thus, the high etching selective ratio layer could be lifted of by Hydrofluoric Acid solution, directly. The user may select one of the processes depends on the efficiency of the removing the substrate.

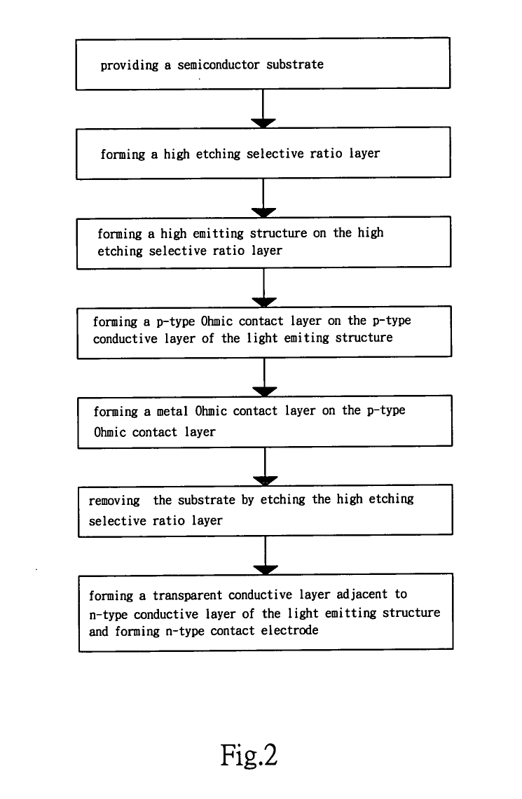

The embodiment of the present invention could refer to the flowchart in the FIG. 2. First, the method includes step of providing a semiconductor substrate and the semiconductor substrate could be semiconductor compound such as GaAs. Then, a high etching selective ratio layer is formed on the semiconductor substrate. The purpose of the high etching selective ratio layer is to provide the lift-off layer in the following lift off process. After that, a light emitting structure is formed on the high etching selective ratio layer, wherein the light emitting structure includes an n-type conductive semiconductor layer, an active layer and a p-type conductive semiconductor layer. The foregoing active layer can be a double hetero-junction structure, a single quantum well structure, or a multiple quantum well structure. Subsequently, and a p-type Ohmic contact layer is formed on the light emitting structure. Because the illumination light rays will be would emitted from the other side, therefore, the consideration of whether the Ohmic contact layer is transparent is irrelvant. The method for forming the Ohmic contact layer includes the steps of the metal deposition and annealing processes. A metal layer is formed on the p-type Ohmic contact layer. The metal layer provides various functions: One is that the metal substrate acts as metal substrate for LED, the other function is to play the role of p electrode. Next, the high etching selective ratio layer and the III-V compound semiconductor substrate are removed. Preferably, the lift-off process is employed by removing the high etching selective ratio layer and thus the III-V compound semiconductor substrate. The material of the high etching selective ration layer is AlAs and the Hydrofluoric Acid solution is utilized as the etching solution. Next, an n-type contact electrode and a transparent conductive layer are formed adjacent to the n-type conductive layer that is closed to the light emitting structure. In general, the transparent conductive layer could adopt Indium Tin Oxide (ITO).

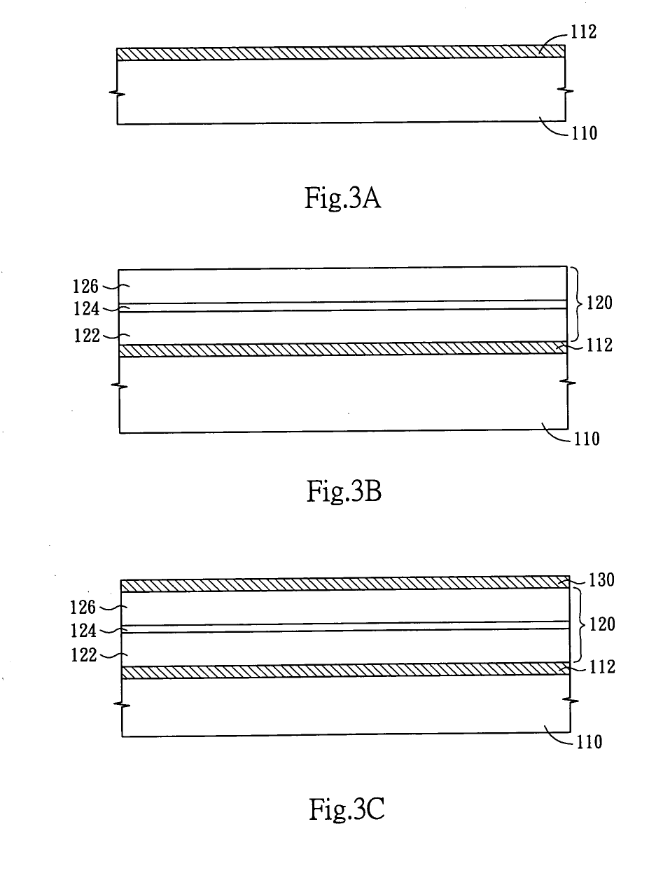

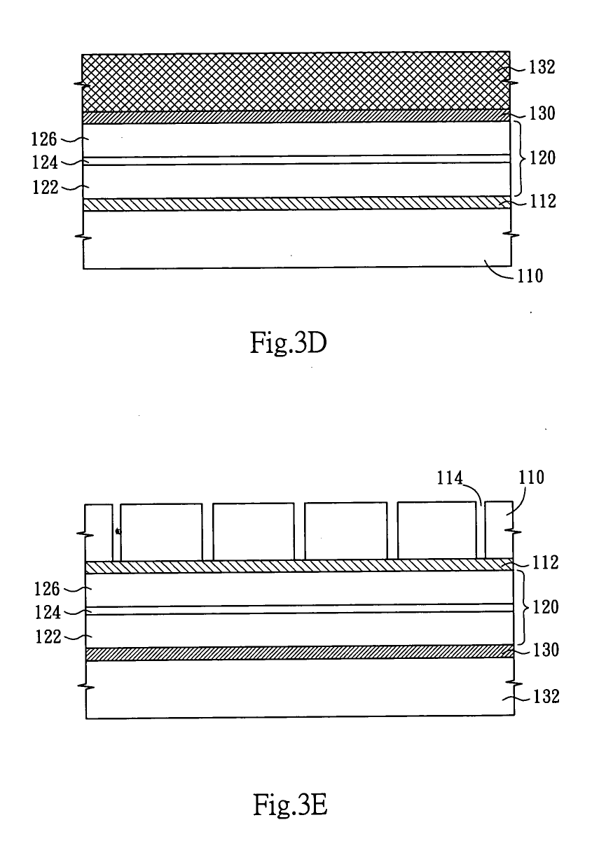

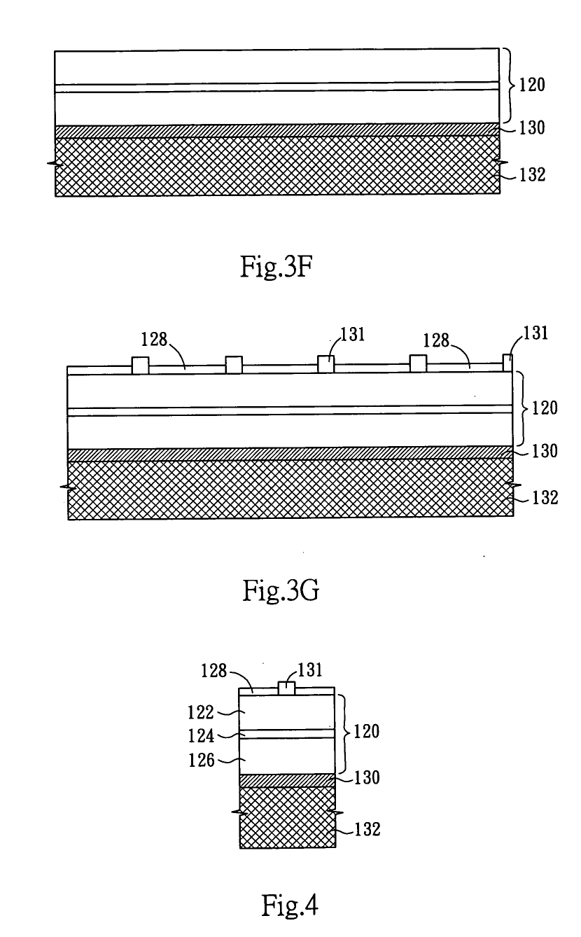

The steps for fabricating LED are shown in FIG. 3. FIG. 3 shows the wafer stage, thus the LED chips will be formed.

Refers to the FIG. 3A, a high etching selective ratio layer 112 is formed on the semiconductor substrate 110. Semiconductor substrate 110 can be GaAs, GaSb, InP, GaP, or other such semiconductor compound. Another option is to select II-VI semiconductor compound such as ZnSe or the IV elemental semiconductor materials such as Si or Ge. It is accepted that the Lattice Constant of the compound or element matches the Lattice Constant of the foregoing high etching selective ratio layer 112.

Since the material of the AlAs possesses a high etch selectivity raito, AlAs is the better candidate to act as the material of the high etching selective ratio layer 112. The method for forming AlAs could be CVD (Chemical Vapor Deposition) like MOCVD (Metal Organic CVD), or PECVD (Plasma Enhanced CVD), or MBE (Molecular Beam Epitaxy). The thickness of the high etching selective ration layer 112 is about 20-20,000 angstroms.

According to the illustration in FIG. 3B, a light emitting structure is formed on the high etching selective ratio layer 112. In the present embodiment, a double heterojunction structure is introduced for interpretation. It's worth mentioning that a homogeneous pn junction, or a single quantum well structure, or a multiple quantum well structure can also be used. The light emitting structure 120 is the light emitting part of LED. The light emitting structure 120 includes an n-type conductive semiconductor layer 122, an active layer 124, and a p-type conductive semiconductor layer 126. Moreover, the present invention can also include a semiconductor layer with the other functions such as a buffer layer, a light out-coupling layer, a current diffusion layer, a current barrier layer, or other suitable non-semiconductor layer. The above-mentioned extra layer would not affect the spirit of the present invention and the extra layer could be added in a proper manner.

Afterwards, a p-type metal Ohmic contact layer 130 is formed on the light emitting structure 120 as the illustration in FIG. 3C. The material of the metal Ohmic contact layer 130 in the present invention could be AuBe, AuZn, PdBe, NiBe, NiZn, PdZn, AuZn, on top of the materials stated above, a layer of Pt or Au, or multiple layers of Pt and Au are formed. The manner for forming the p-type metal Ohmic contact layer 130 includes two processes including coating and annealing. It is consented to choose thermal evaporation, sputtering, or E-beam evaporation as the mode of the coating. Ohmic contact will be formed through the process of the annealing. Furthermore, the thickness of the metal Ohmic contact layer 130 is about 50-30,000 angstrom. The metal Ohmic contact layer 130 is employed to provide a fine Ohmic contact, and it is also a fine reflector of LED to reflect light emitted toward the p-type semiconductor layer toward the n-type semiconductor layer.

According to the FIG. 3D, a thick metal layer 132 is formed on the metal Ohmic contact layer 130. The functions of the metal layer 132 include acting a substrate for LED, the other one is to play the role of p electrode. On the grounds that the previous semiconductor substrate 110 would be removed in the present invention, LED would adopt the metal layer 132 as the substrate lastly. In addition, the metal substrate holds various virtues such as providing a fine heat dissipation and providing a fine utility for reflecting. For instance, the current diffuses evenly and flow toward LED structure for increasing emitting area. The metal layer 132 could be formed by plating, printing, spin coating or spray. In the present invention, the material of the metal layer 132 could be Gold, Silver, Copper, Molybdenum, Nickel, silver epoxy, or solder paste. And the thickness of the metal layer 132 is about 10-200 μm.

Accordingly, the semiconductor substrate 110 is separated as the illustration of the FIG. 3E. Selecting the manner of cutting substrate 110 would provide a superior etch effect for large wafer area. In view of the following process directing to the semiconductor substrate 110, the high etching selective ratio layer 112, and the p-type conductive semiconductor 122, reversing the direction of the figures for facile description. There are diverse techniques for cutting the semiconductor substrate 110 until the high etching selective ratio layer 112 exposes such as dry etching, wet etching, or cutting the semiconductor layer via dicing saw or laser beams.

Accordingly, as the illustration of the FIG. 3F, the semiconductor substrate 110 and the high etching selective ratio layer 112 are removed by means of the lift-off process. The etching rate of the Hydrofluoric Acid solution to the high etching selective ratio layer 112 is about 10⁸ times greater than to etch the semiconductor 1120 and p-type conductive semiconductor layer 112. Viz., after the high etching selective ratio layer 112 is etched entirely, the semiconductor substrate 110 and the light emitting structure 120 is still maintained but the entire semiconductor substrate 110 is lift off for removing from LED. The surface of the p-type conductive semiconductor layer 122 after lift-off process still possesses a fine crystalline surface for forming subsequent layer thereon by epitaxy. Therefore in the present embodiment, the next step is to dip the semiconductor substrate 110 of LED in the Hydrofluoric Acid solution for the high etching selective ratio layer 112 to contact with the Hydrofluoric Acid solution. After etching the high etching selective ratio layer 112, the semiconductor substrate 110 will be lifted off and stayed in the Hydrofluoric Acid solution.

According to the FIG. 3G, an n electrode 131 and a transparent conductive layer 128 are formed on the n-type conductive semiconductor layer 122 respectively. The transparent conductive layer 128 could be the ITO (Indium Tin Oxide), the Indium Zinc Oxide (IZO), or the other transparent metal layer. Seeing that the ITO or the IZO has the Ohmic contact with the n-type conductive semiconductor layer 122, the current from the n electrode 131 will distribute on the ITO layer 128 evenly and then the current will flow downward to the n-type conductive semiconductor layer 122. Consequently, the most part of the light emitting area can be efficiently utilized.

FIG. 4 represents the chip of LED that has been cut.

Since the transparent conductive material nowadays has the Ohmic contact with the n-type conductive semiconductor layer. In the present invention, the transparent conductive material such as the ITO or the IZO is formed on the n-type conductive semiconductor layer for ameliorating a variety of problems of LED and ameliorating the efficiency of LED. Because the illumination emitted from the n-type conductive semiconductor layer, it is suitable with the transparent conductive material has the Ohmic contact with the n-type conductive semiconductor layer. Owing to the Ohmic contact between the transparent conductive material and n-type conductive semiconductor layer, the current will diffuse in the transparent conductive material and n-type conductive semiconductor layer. Thus, the active emitting area of LED will increase. Additionally, a proper metal Ohmic contact layer and the metal substrate are formed on the p-type conductive semiconductor layer. The light emitted toward the p-type conductive semiconductor layer will be reflected toward the n-type conductive semiconductor layer via the metal substrate. Further, the metal substrate could be a p electrode and could promote the heat dissipation for LED. Furthermore, adopt the lift-off process for removing the semiconductor substrate could lift off between two different kinds of material of the layer.

As is understood by a person skilled in the art, the foregoing preferred embodiments of the present invention are illustrated of the present invention rather than limiting of the present invention. It is intended to cover various modifications and similar arrangements included within the spirit and scope of the appended claims, and the scope of which should be accorded the broadest interpretation so as to encompass all such modifications and similar structure. While the preferred embodiment of the invention has been illustrated and described, it will be appreciated that various changes can be made therein without departing from the spirit and scope of the invention.

We claim:

1. A method for fabricating LED, said method comprises:
providing a semiconductor substrate;
forming a high etching selective ratio layer on said semiconductor substrate;
forming a light emitting structure on said high etching selective ratio layer, wherein said light emitting structure includes a n-type conductive semiconductor layer on said high etching selective ratio layer and a p-type conductive semiconductor layer on n-type conductive semiconductor layer;
forming a p-type Ohmic contact layer on said light emitting structure;
forming a metal substrate on said p-type Ohmic contact layer;
removing said semiconductor substrate and said high etching selective ratio layer;
forming a n-type contact electrode adjacent to said n-type conductive semiconductor layer; and
forming a transparent conductive layer adjacent to said n-type conductive semiconductor layer.

2. The method for fabricating LED as set forth in claim 1, wherein said semiconductor substrate includes the III-V compound semiconductor substrate.

3. The method for fabricating LED as set forth in claim 2, wherein said III-V compound semiconductor substrate includes GaAs.

4. The method for fabricating LED as set forth in claim 3, wherein said high etching selective ratio layer includes AlAs.

5. The method for fabricating LED as set forth in claim 2, wherein said III-V compound semiconductor substrate includes ZnSe, Si, Ge, GaSb, Inp, or GaP.

6. The method for fabricating LED as set forth in claim 5, wherein said high etching selective ratio layer includes AlAs or AlGaAs.

7. The method for fabricating LED as set forth in claim 1, said steps for forming said p-type Ohmic contact layer comprise:
forming a p-type metal contact layer on said p-type conductive semiconductor layer; and
said p-type metal contact layer being formed to be said p-type Ohmic contact layer by performing an annealing process.

8. The method for fabricating LED as set forth in claim 2, said steps for removing said semiconductor substrate and said high etching selective ratio layer comprise:
cutting said III-V compound semiconductor substrate until said high etching selective ratio layer; and
lifting off said high etching selective ratio layer and said semiconductor substrate by Hydrofluoric Acid solution.

9. The method for fabricating LED as set forth in claim 1, wherein said transparent conductive layer includes Indium Tin Oxide (ITO).

10. The method for fabricating LED as set forth in claim 1, wherein said light emitting structure includes an active layer locating between said n-type conductive semiconductor layer and said p-type conductive semiconductor layer.

11. A method for fabricating LED, said method comprises:
providing a III-V compound semiconductor substrate;
forming a lift-off layer on said III-V compound semiconductor substrate;
forming a n-type conductive semiconductor layer on said lift-off layer;
forming an active layer on n-type conductive semiconductor layer;
forming a p-type conductive semiconductor layer on said active layer;
forming a p-type metal contact layer on said p-type conductive semiconductor layer;
said p-type metal contact layer being formed to be said p-type Ohmic contact layer by performing an annealing process;
forming a metal layer on said p-type Ohmic contact layer;
cutting said III-V compound semiconductor substrate until said lift-off layer;
removing said lift-off layer and said semiconductor substrate by lift-off process;
forming a n-type contact electrode adjacent to said n-type conductive semiconductor layer; and
forming a Indium Tin Oxide (ITO) layer adjacent to said n-type conductive semiconductor layer.

12. The method for fabricating LED as set forth in claim 11, wherein said III-V compound semiconductor substrate includes GaAs.

13. The method for fabricating LED as set forth in claim 12, wherein said lift-off layer includes AlAs.

14. The method for fabricating LED as set forth in claim 12, wherein said III-V compound semiconductor substrate includes ZnSe, Si, Ge, GaSb, InP, or GaP.

15. The method for fabricating LED as set forth in claim 14, wherein said lift-off layer includes AlAs or AlGaAs.

16. The method for fabricating LED as set forth in claim 11, wherein Hydrofluoric Acid solution is introduced during said lift-off process for removing said lift-off layer and said semiconductor substrate.

17. The method for fabricating LED as set forth in claim 11, wherein said light emitting structure includes an active layer locating between said n-type conductive semiconductor layer and said p-type conductive semiconductor layer.
